(19) United States
(12) Patent Application Publication
(10) Pub. No.: US 2007/0256812 A1
(43) Pub. Date: Nov. 8, 2007

(54) Multidirectional heat dissipating structure

(76) Inventor: Wen-Chen Wei, Wugu Township (TW)

Correspondence Address: Wen-Chen Wei, P.O. Box 6-57, Junghe, Taipei, 235, TW

(21) Appl. No.: 11/406,311

(22) Filed: Apr. 19, 2006

(51) Int. Cl. H05K 7/20

(52) U.S. Cl. 165/80.3; 165/121; 361/697

(57) ABSTRACT

A multidirectional heat dissipating structure that joins and assembles a plurality of heat dissipating fins, length of each of which vary, and can be arranged and assembled to form a plurality of flow guiding plates, each of which assumes a certain angle in accordance with the direction of air, thereby forming an appropriate air channel that smoothly guides an air flow from a fan, causing cool air to rapidly flow towards heat conduction areas formed by spacings between the heat dissipating fins, thereby accelerating dissipation of heat from a heat source at a bottom portion of the heat dissipating fins. Moreover, the heat dissipating structure is applicable for use in various horizontal blowing and downward blowing heat dissipating devices.

### BACKGROUND OF THE INVENTION

(a) Field of the Invention

The present invention relates to a multidirectional heat dissipating structure, and more particularly to a heat dissipating structure that uses heat dissipating fins of different length assembled to structure flow guiding plates that form an air channel of certain angle, which enables cool air to follow the air channel and be rapidly guided into the heat dissipating fins to dissipate hot air and effectively reduce temperature.

(b) Description of the Prior Art

Accordingly, in order to resolve the problem of overheating of components within a host computer, in general, a heat dissipating device is installed on top of the heating electronic components, which is able to dissipate heat energy from the high temperature produced by the electronic components. Moreover, heat dissipating fins of a prior art heat dissipating device are disposed on a bottom plate of a heat sink, and the bottom plate is placed in close contact with the heating electronic components, thereby enabling the heat dissipating fins to dissipate the heat energy from the high temperature produced by the electronic components when operating. Although cost of such a heat dissipating device is low, however, speed of heat conduction is relatively slow, and is only suitable for use in computers operating at relatively low speeds. Hence, the heat dissipating effect of prior art heat dissipating devices is limited when used to dissipate heat from heating electronic components that are required to operate at high speed or for long periods of time. Hence, simply replying on the heat dissipating fins is unideal and insufficient to satisfy heat dissipation requirements. Consequently, present day improved models of heat dissipating devices include an additionally installed fan that uses a forced convection direction to dissipate heat energy. Referring to FIG. 1, which shows a prior art heat dissipating device primarily structured to include an additional fan (2) installed in an appropriate space beside heat dissipating fins (1). The heat dissipating fins (1) are arranged to assume a channeled configuration and spacings form a plurality of hot air outlets (3). When the heat dissipating device is installed on a surface of heating electronic components and the fan (2) is running, cool air enters air inlets (4) and is guided into and blown over the heat dissipating fins (1), which enables the cool air to disperse heat energy conducted upwards by the electronic components, thereby achieving heat dissipation functionality. However, because of the perpendicular plane surface configuration of the channeled cool air flow inlets and hot air outlets of the prior art heat dissipating device, thus, when cool air is blown in, it inverts and forms an air wall that obstructs the fanned air flow, thereby easily forming a stagnant air layer that causes a heat source to build up between the heat dissipating fins and the fan, unavailingly consuming fan power. Hence, because heat dissipation effectiveness of the fan can only cope with general applications, thus, some business operators have increased air speed of the fan to improve effectiveness. However, noise generated by the fan is even greater because of the corresponding increase in air pressure produced by the rotating fan, causing irritation to the user.

### SUMMARY OF THE INVENTION

Hence, in light of the shortcomings in structural design of the aforementioned prior art heat dissipating device, the inventor of the present invention attentively researched various methods to resolve such drawbacks and design an heat dissipating device having good heat dissipation effectiveness in the limited volume of space within a host computer, which, following continuous research and improvements, culminated in the design of a multidirectional heat dissipating structure. Stated more specifically, the present invention uses stamping technology to stamp single heat dissipating strips and form heat dissipating fins that can be mutually joined and arranged in row form. The heat dissipating fins are further formed in different lengths, which can be arranged and assembled to form a plurality of flow guiding plates, each of which assumes a certain angle in accordance with the direction of air from a fan, thereby forming an appropriate converging air channel that smoothly guides the direction of air flow from a fan when running, causing cool air to rapidly flow towards heat conduction areas formed by spacings between the heat dissipating fins, thereby accelerating dissipation of heat from a heat source at a bottom portion of the heat dissipating fins. Furthermore, when a fan is running, the guided air flow is obstructed by the flow guiding plates, which break up the whirling air wall produced by the air flow, thereby preventing reflective collision of the air flow and avoiding producing an inverse air flow phenomenon. The included angle formed by the flow guiding plates is also able to diminish the air flow field, thereby increasing air pressure blowing towards the heat conduction areas, and correspondingly increasing speed of the guided air flow from the fan, which is channeled by the flow guiding plates to achieve rapid and continuous circulation, thus avoiding occurrence of airflow stagnation and achieving optimum heat dissipation functionality. The present invention assuredly resolves the problem of overheating of computer electronic components. Furthermore, because of the flat plate-type assembled configuration of the plurality of heat dissipating fins of the present invention, thus, apart from forming maximum heat dissipation surface area, moreover, arrangement of the lengths of the heat dissipating fins can be preset to accommodate disposition and angle of the fan on the motherboard, thereby facilitating application in various horizontal blowing and downward blowing heat dissipating devices.

Hence, a primary objective of the present invention is to resolve the limitation in heat dissipation effectiveness of prior art computer heat dissipating structures by using heat dissipating fins of different length assembled to structure flow guiding plates and form an air channel of certain angle, which enables cool air to follow the air channel and be rapidly guided into the heat dissipating fins to dissipate hot air and effectively reduce temperature, thereby achieving optimum heat dissipation effectiveness.

Another objective of the present invention is to use the flow guiding plates to reduce air blockage without increasing air pressure from a fan, and to realize full functionality of the fan and decrease fan noise.

Yet another objective of the present invention is to use a flat plate-type assembled configuration of the plurality of heat dissipating fins of different length to facilitate application in various horizontal blowing and downward blowing heat dissipating devices.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an elevational view of a prior art heat dissipating device.

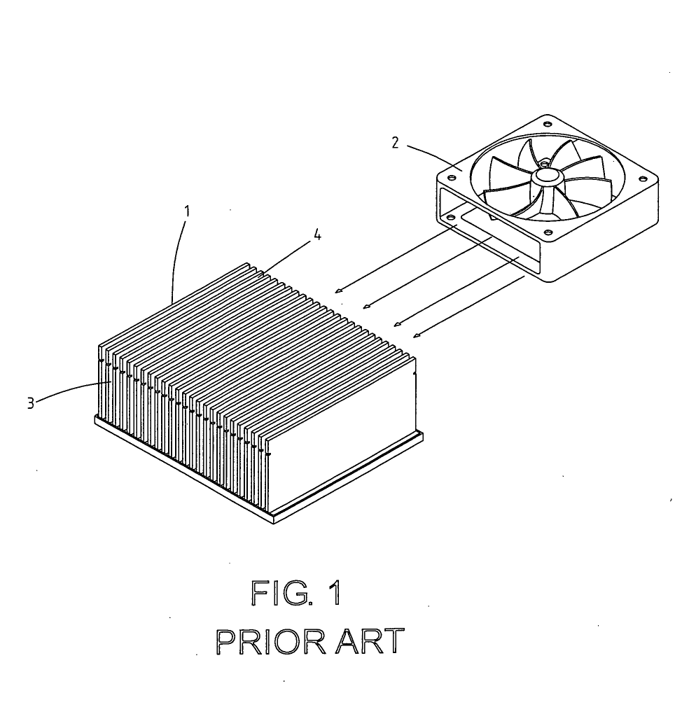

FIG. 2 shows an exploded elevational structural view of an embodiment according to the present invention.

FIG. 3 shows an assembled elevational structural view of an embodiment according to the present invention.

FIG. 4 shows a schematic view of the embodiment depicting guiding of air according to the present invention.

FIG. 5 shows a schematic view of another embodiment depicting guiding of air according to the present invention.

FIG. 6 shows a schematic view of yet another embodiment according to the present invention.

### DETAILED DESCRIPTION OF THE PREFERRED EMBODIMENTS

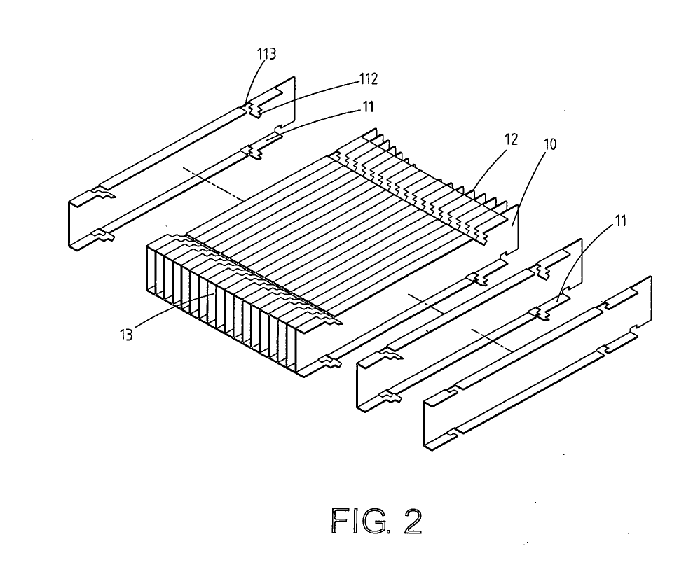

Referring to FIG. 2, which shows an exploded three-dimensional structural view of a preferred embodiment of a multidirectional heat dissipating structure of the present invention, wherein:

Heat dissipating fins (10) are molded laminate long strips, top and bottom end edges of each of which are horizontally bent to from heat conduction wing fins (11) thereat. Clasp slots (113) are formed on each of the heat conduction wing fins (11), and clasp hooks (112) respectively extend in the same direction from the clasp slots (113). A bend in each of the clasp hooks (112) forms an inverted fastener, which enable assembly of the corresponding front and back heat dissipating fins (10) therewith, thereby allowing a set of the heat dissipating fins (10) to be assembled one strip at a time without resulting in the heat dissipating fins (10) arbitrarily coming apart. The present invention is primarily characterized in that when stamping, an end of each of the heat dissipating fins (10) is frontward extended to extrude a predetermined length, thereby forming extended sections that enable the heat dissipating fins (10) of different length to be respectively formed when stamp forming the extended sections. After primary stamping, the extended sections of each of the heat dissipating fins (10) enable arranging and assembling various different stratified flow guiding plates (12).

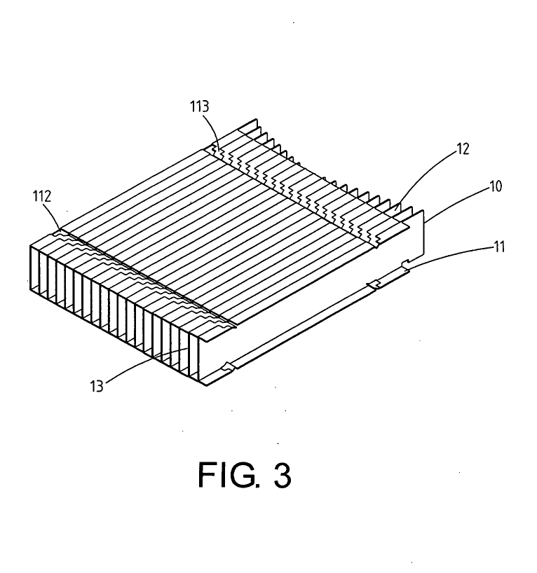

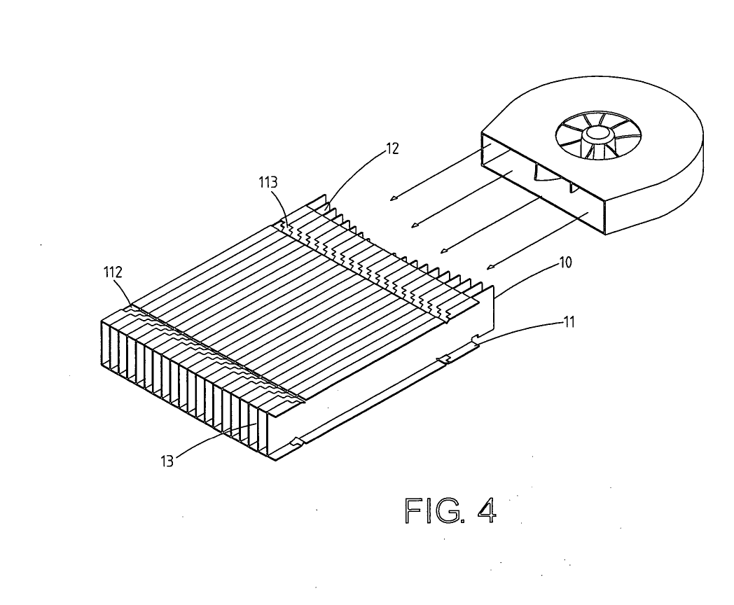

Referring to FIGS. 3 and 4, which show an assembled three-dimensional view and a schematic view depicting guiding of air of the present invention respectively, wherein when assembling the heat dissipating fins (10), the clasp hooks (112) of the rear heat dissipating fin (10) are clasped within the respective clasp slots (113) of the front heat dissipating fin (10) in such a manner that each of the heat dissipating fins (10) are successively joined together to complete assembly of the heat dissipating structure. When combining the heat dissipating fins (10) to assemble the heat dissipating structure, because of mutual combining of the heat conduction wing fins (11), thus, bottom portions form a compact heat conducting contact surface that provides the heat dissipating fins (10) with an extensive absorbing and heat dissipating area, which is able to make total contact with the heat source and fully absorb the hot air radiating from the electronic components. Furthermore, when combining the heat dissipating fins (10), width of the bend formed by each of the heat conduction wing fins (11) fashion conduit type aligned spaces constituting heat conduction areas (13). When the fan is running and blowing an air flow towards the heat dissipating fins (10) from an air outlet, the flow guiding plates (12) are able to smoothly guide the air flow through the heat conduction areas (13). Furthermore, an included angle formed by the flow guiding plates (12) to accommodate a whirling air channel from the fan prevents reflective collision of the air flow and avoids producing an inverse air flow phenomenon. Hence, use of the flow guiding plates (12) not only counterchecks the inverse air flow, moreover, the included angle formed by the flow guiding plates (12) is also able to diminish the air flow field, thereby increasing air pressure blowing towards the heat conduction areas (13) and correspondingly increasing speed of the air flow, thus enabling unhindered circulation of the air flow, and avoiding the occurrence of airflow stagnation. Hence, the present invention is able to effectively increase convection efficiency of air passing through the heat dissipating fins (10), thereby quickly and steadily conveying cool air into the heat dissipating fins (10) and dispersing heat energy away from the heating electronic components, thus achieving superior heat dissipation functionality. Furthermore, the present invention is able to realize full functionality of the fan, and decrease fan noise.

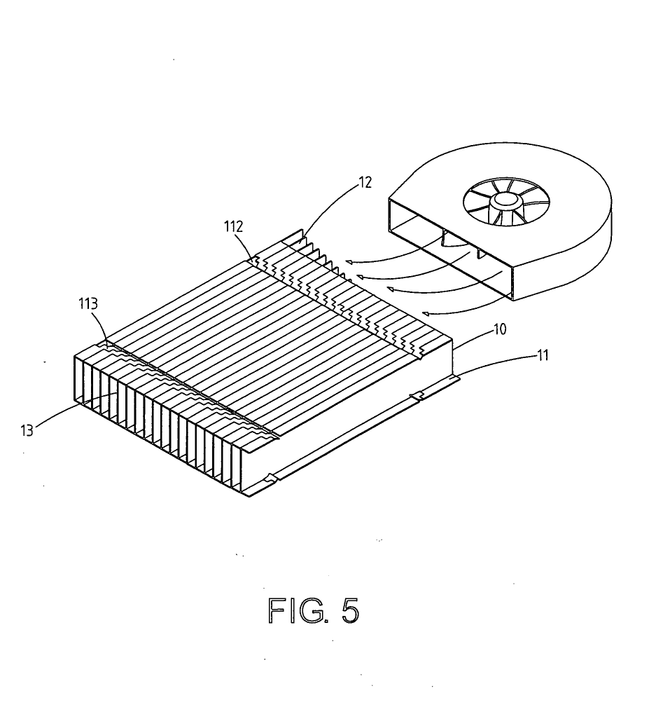

Referring to FIG. 5, which shows a schematic view of another embodiment of the present invention, wherein in order for the present invention to be able to accommodate computer motherboards of different design, the flow guiding plates (12) can be arranged and assembled according to disposed position of the fan air outlet by matching length of the flow guiding plates (12) with angle of air direction from the fan outlet to form an appropriate air channel. When the air outlet of the fan is positioned on the right side, the present invention is assembled so that length of each of the flow guiding plates (12) successively diminishes from a left side end to a right side end thereof, thereby enabling the flow guiding plates (12) to smoothly and quickly guide the air flow from the fan into the heat conductions areas (13) formed from spacings between the heat dissipating fins (12), thus realizing sustained and rapid dissipation and dispersal of the heat energy.

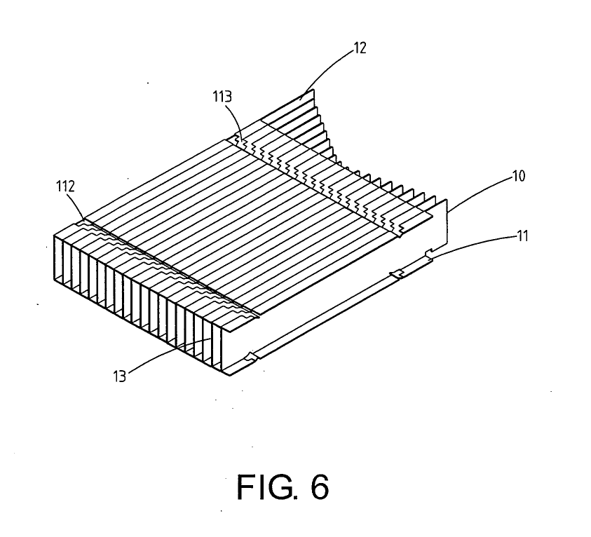

Referring to FIG. 6, it can be appreciated that the present invention can also be structured so that disposition of the flow guiding plates (12) of varying length forms an arc-shaped configured arrangement, thereby accommodating and guiding a strong air flow blown from an air outlet into the main positioned heat conduction areas (13) so as to improve heat dissipation of the main positioned concentrated heat source area, thereby enabling the remaining air flow to be separately blown into other heat dissipation areas to achieve full heat dissipation functionality.

Furthermore, when combining the heat dissipating fins (10) to form a set of heat dissipating fins, arrangement of length and angle of the heat dissipating fins (10) can be preset to accommodate disposition and angle of the fan on the motherboard, and to present maximum heat dissipation surface area to the air flow, Hence, the present invention is applicable for use in various horizontal blowing and downward blowing heat dissipating devices.

Worthy of particular mention is that the heat dissipating fins (10) of the present invention can be integrated stamp formed and assembled, which not only quickens speed of production, moreover, it also fully utilizes area and space, economizes on material, and significantly reduces development cost.

In conclusion, the multidirectional heat dissipating structure of the present invention is a practical and complete invention, which is not only provided with originality and superior practicability, moreover, structural configuration and space usage are not found in prior art. Furthermore, stamping technology and design used to structure and assemble the heat dissipating fins (10) clearly improves speed of heat dissipation, and assuredly enhances the heat dissipation function for computer electronic components. The present invention is an advancement and a breakthrough in conventional prior art, and not an obvious simple adaptation, and clearly complies with essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A multidirectional heat dissipating structure comprising a plurality of heat dissipating fins, ends of each of which are bent to form heat conduction wing fins, and a plurality of spacings are formed when combining and assembling the heat conduction wing fins that serve as heat conduction areas; the multidirectional heat dissipating structure is characterized in that:
length of each of the heat dissipating fins vary, and can be arranged and assembled to form a plurality of flow guiding plates, each of which assumes a certain angle in accordance with the direction of air, thereby forming an appropriate converging air channel that smoothly guides an air flow from a fan when running, causing cool air to rapidly flow towards the heat conduction areas formed by the spacings between the heat dissipating fins, thereby accelerating dissipation of heat from a heat source at a bottom portion of the heat dissipating fins.

2. The multidirectional heat dissipating structure according to claim 1, wherein the flow guiding plates are prearranged and assembled to form an angle in conformance with position, angle or air outlet of a fan.
